(19) United States
(12) Patent Application Publication
(10) Pub. No.: US 2026/0183805 A1
(43) Pub. Date: Jul. 2, 2026

(54) SUBSTRATE PROCESSING APPARATUS INCLUDING ULTRASONIC NOZZLE AND METHOD FOR DRIVING THE SAME

(71) Applicant: SEMES CO., LTD., Chungcheongnam-do (KR)

(72) Inventors: Ie Goo YOON, Chungcheongnam-do (KR); Soon Kab KWON, Gyeongsangnam-do (KR)

(21) Appl. No.: 19/428,309

(22) Filed: Dec. 22, 2025

(30) Foreign Application Priority Data
Dec. 30, 2024 (KR) 10-2024-0200027

(51) Int. Cl. B08B 3/12; B08B 3/04; B08B 3/08; B08B 13/00; G03F 1/82; H10P 72/00

(52) U.S. Cl. CPC B08B 3/123; B08B 3/048; B08B 3/08; B08B 13/00; H10P 72/0414; G03F 1/82

(57) ABSTRACT

A substrate processing apparatus with improved cleaning efficiency is provided. The substrate processing apparatus includes: a support member configured to support a substrate; a chemical solution supplier configured to supply chemical solution to the substrate; a sonic oscillator including an ultrasonic nozzle; a home port provided on one side of the support member and configured to accommodate the ultrasonic nozzle in a standby state; and a controller configured to control the support member, the chemical solution supplier, the sonic oscillator, and the home port, wherein the controller controls the ultrasonic nozzle to vibrate the chemical solution applied on the substrate during a cleaning period, and controls the ultrasonic nozzle to vibrate in the home port during a standby period to remove particles adhering to the ultrasonic nozzle.

### CROSS-REFERENCE TO RELATED APPLICATION

This application claims priority from Korean Patent Application No. 10-2024-0200027 filed on Dec. 30, 2024 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a substrate processing apparatus including an ultrasonic nozzle and a method for driving the same.

### 2. Description of the Related Art

If particles are not removed from a substrate, they can cause malfunction or failure of circuits. As integration density in semiconductor devices increases, permissible particle levels are becoming more stringent. To improve cleaning efficiency, a chemical solution may be applied to the substrate, and the substrate may be cleaned by vibrating the chemical solution using a vibrator.

### SUMMARY

An objective of the present disclosure is to provide a substrate processing apparatus with improved cleaning efficiency.

Another objective of the present disclosure is to provide a driving method of the substrate processing apparatus with improved cleaning efficiency.

The objectives of the present disclosure are not limited to those mentioned above, and other objectives not explicitly stated will be clearly understood by those skilled in the art based on the following description.

According to an aspect of the present disclosure, a substrate processing apparatus includes: a support member configured to support a substrate; a chemical solution supplier configured to supply chemical solution to the substrate; a sonic oscillator including an ultrasonic nozzle; a home port provided on one side of the support member and configured to accommodate the ultrasonic nozzle in a standby state; and a controller configured to control the support member, the chemical solution supplier, the sonic oscillator, and the home port, wherein the controller controls the ultrasonic nozzle to vibrate the chemical solution applied on the substrate during a cleaning period, and controls the ultrasonic nozzle to vibrate in the home port during a standby period to remove particles adhering to the ultrasonic nozzle.

According to another aspect of the present disclosure, a substrate processing apparatus includes: a rotary chuck configured to support a substrate; a chemical solution supplier configured to supply chemical solution to the substrate; a sonic oscillator including an ultrasonic nozzle that vibrates by a vibrator's vibration; a home port provided on one side of the rotary chuck and configured to accommodate the ultrasonic nozzle in a standby state; and a controller configured to control the rotary chuck, the chemical solution supplier, the sonic oscillator, and the home port, wherein the home port includes: a bath with an opening at the top; and a cleaning solution supplier configured to supply cleaning solution to the bath, the cleaning solution supplier continuously supplies cleaning solution into the bath, causing the cleaning solution to overflow, during a cleaning period, the ultrasonic nozzle vibrates at a first output to vibrate the chemical solution applied on the substrate, during a standby period, the ultrasonic nozzle is submerged in the cleaning solution through the opening of the home port, the standby period includes consecutive first, second, and third periods, during the first period, the ultrasonic nozzle vibrates at a second output greater than the first output, thereby detaching particles from the ultrasonic nozzle, during the second period, the ultrasonic nozzle stops vibrating and the detached particles overflow out of the bath with the cleaning solution, and during the third period, the ultrasonic nozzle vibrates again.

According to still another aspect of the present disclosure, method for driving a substrate processing apparatus comprises: placing a substrate on a support member; supplying chemical solution onto the substrate; cleaning the substrate by vibrating the chemical solution applied on the substrate using an ultrasonic nozzle; moving the ultrasonic nozzle to a home port; and removing particles adhering to the ultrasonic nozzle by vibrating the ultrasonic nozzle in the home port.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing exemplary embodiments thereof in detail with reference to the attached drawings, in which:

FIG. 1 is a conceptual view illustrating a substrate processing system according to some embodiments of the present disclosure;

FIG. 2 is a plan view illustrating a substrate processing apparatus according to some embodiments of the present disclosure;

FIG. 3 is a side view illustrating the substrate processing apparatus according to some embodiments of the present disclosure;

FIG. 4 is a flowchart illustrating the operation of the substrate processing apparatus according to some embodiments of the present disclosure;

FIGS. 5 and 6 are conceptual views illustrating a cleaning operation of an ultrasonic nozzle;

FIG. 7 is a diagram illustrating a substrate cleaning operation using the ultrasonic nozzle;

FIG. 8 is a diagram illustrating an ultrasonic nozzle cleaning operation;

FIGS. 9 to 11 are diagrams illustrating other ultrasonic nozzle cleaning operations;

FIG. 12 is a diagram illustrating another ultrasonic nozzle cleaning operation; and

FIG. 13 is a flowchart illustrating the operation of a substrate processing apparatus according to some embodiments of the present disclosure.

### DETAILED DESCRIPTION

Hereinafter, preferred embodiments of the present disclosure will be described in detail with reference to the accompanying drawings. The advantages and features of the present disclosure, and methods of achieving them, will be apparent from the embodiments described below in detail with reference to the drawings. However, the present disclosure is not limited to the embodiments disclosed herein but may be embodied in various forms. Rather, the embodiments are provided so that the present disclosure is complete and to fully convey the scope of the invention to those skilled in the art. The present disclosure is defined only by the claims. Throughout the specification, the same reference numerals denote the same elements.

Spatially relative terms such as “below,” “beneath,” “lower,” “above,” and “upper” may be used to conveniently describe the relationship of one element or component to another element or component as illustrated in the drawings. Spatially relative terms are intended to encompass different orientations of a device or element in use or operation in addition to the orientations depicted in the drawings. For example, if the device in the drawings is turned over, an element described as being “below” or “beneath” another element may be positioned “above” the other element. Thus, the exemplary term “below” may encompass both below and above directions. The device may also be oriented in other directions, and accordingly, spatially relative terms may be interpreted based on orientation.

Although the terms “first,” “second,” and the like may be used to describe various elements, components, and/or periods, these elements, components, and/or periods are not limited by such terms. These terms are used only to distinguish one element, component, or period from another. Accordingly, a first element, component, or period described below may be a second element, component, or period without departing from the scope of the present disclosure.

Hereinafter, embodiments of the present disclosure will be described in detail with reference to the accompanying drawings. In the description with reference to the drawings, the same reference numerals will be assigned to the same or corresponding elements regardless of figure numbers, and redundant descriptions thereof will be omitted.

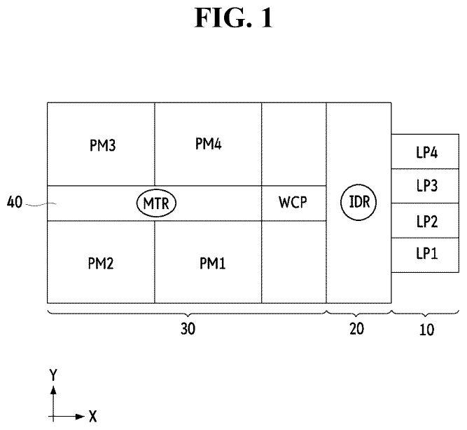

FIG. 1 is a conceptual view illustrating a substrate processing system according to some embodiments of the present disclosure.

Referring to FIG. 1, the substrate processing system according to some embodiments of the present disclosure includes a load port 10, an index module 20, a process module 30, and a transfer module 40. The load port 10, the index module 20, and the process module 30 may be arranged along a first direction (X-axis direction).

The load port 10 includes stages LP1 to LP4 on which containers storing a plurality of substrates are placed. The containers may be, for example, Front Opening Unified Pods (FOUP), Front Opening Shipping Boxes (FOSBs), or the like, but are not limited thereto. A plurality of stages may be arranged along a second direction (Y-axis direction). For example, four stages are illustrated.

The index module 20 is arranged between the load port 10 and the process module 30. For example, the index module 20 includes a rail installed inside an index chamber and an index robot IDR that moves along the rail. The index robot IDR, which includes an arm and a hand, picks up a substrate located at the load port 10 and transfers it to a buffer chamber WCP.

The process module 30 may include the buffer chamber WCP and a plurality of process chambers PM1 to PM4.

The buffer chamber WCP temporarily stores a substrate delivered by the index robot IDR of the index module 20. In addition, the buffer chamber WCP may temporarily store a substrate on which a predetermined process in at least one of the process chambers PM1 to PM4 has been completed.

The transfer module 40 is arranged to extend along the first direction (X direction). The transfer module 40 includes a guide rail inside, and a transfer robot MTR that moves along the guide rail is installed.

A pair of process chambers PM1 and PM2 may be arranged on one side of the transfer module 40 in the second direction (Y-axis direction), and another pair of process chambers PM3 and PM4 may be arranged on the other side of the transfer module 40. However, the present disclosure is not limited to this.

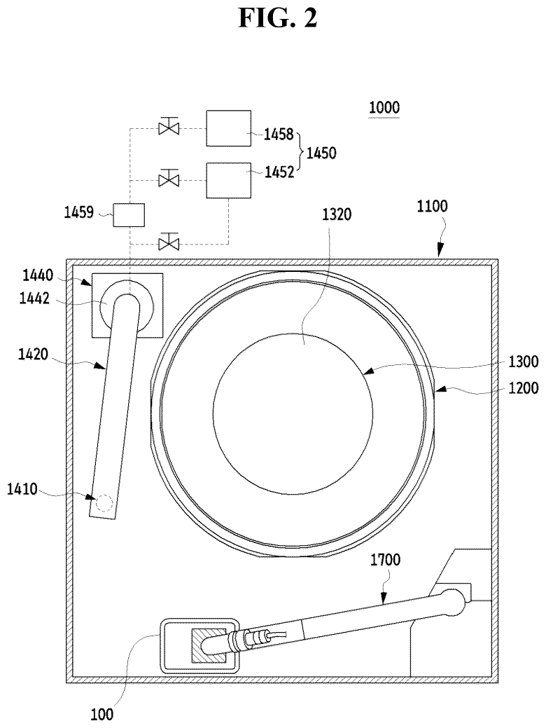

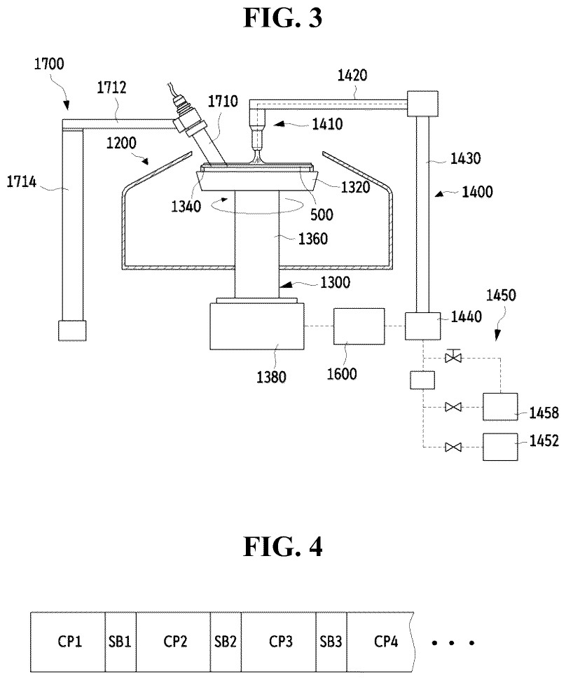

FIG. 2 is a plan view illustrating a substrate processing apparatus according to some embodiments of the present disclosure. FIG. 3 is a side view illustrating the substrate processing apparatus according to some embodiments of the present disclosure. The substrate processing apparatus illustrated in FIGS. 2 and 3 may correspond to at least one of the process chambers PM1 to PM4 in FIG. 1.

Referring to FIGS. 2 and 3, a substrate processing apparatus 1000 includes a chamber 1100, a container 1200, a support member 1300, a chemical solution supplier 1400, a sonic oscillator 1700, a home port 100, and a controller 1600. The controller 1600 controls the operation of at least one of the container 1200, the support member 1300, the chemical solution supplier 1400, the sonic oscillator 1700, or the home port 100.

The chamber 1100 provides an enclosed interior space. A fan filter unit may be installed on the upper wall of the chamber 1100. The fan filter unit generates a vertical airflow directed downwards within the interior space of the chamber 1100.

The container 1200 is arranged inside the chamber 1100. The container 1200 prevents a chemical solution used in a process and fumes generated during the process from splashing or leaking outside. The container 1200 includes a space, open at the top, for processing a substrate 500. The substrate 500 may include a wafer, a glass substrate, a mask, or the like.

The support member 1300 is positioned within the container 1200. The support member 1300 supports the substrate 500 during processing. The support member 1300 includes a support plate 1320, a support shaft 1360, and a support plate driver 1380.

The support plate 1320 is generally circular and has a diameter larger than the substrate 500. The support plate 1320 supports the substrate 500 such that, during chemical solution supply, the substrate 500 faces upward. Chucking pins may be provided on the upper surface of the support plate 1320. The chucking pins protrude upward from the upper surface of the support plate 1320 to prevent the substrate 500 from deviating laterally due to centrifugal force when the support plate 1320 rotates. The central lower portion of the support plate 1320 is connected to the support shaft 1360, which supports the support plate 1320 and corresponds with its central axis. The support plate driver 1380 is connected to the lower end of the support shaft 1360 and rotates the support plate 1320. The support plate driver 1380 transmits rotational force to the support plate 1320 via the support shaft 1360 and is controlled by the controller 1600. The support plate driver 1380 may include a motor.

A lifting unit (not illustrated) moves the container 1200 vertically so that the relative height of the support plate 1320 to the container 1200 can be adjusted. The lifting unit lowers the container 1200 so that the support plate 1320 protrudes from the top of the container 1200 when the substrate 500 is loaded onto or unloaded from the support plate 1320.

The chemical solution supplier 1400 is provided on one side of the container 1200. The chemical solution supplier 1400 supplies a processing solution onto the upper surface of the substrate 500 to remove contamination. The chemical solution supplier 1400 includes a nozzle 1410, a nozzle arm 1420, an arm support shaft 1430, a nozzle driver 1440, and a processing solution supply unit 1450.

The processing solution supply unit 1450 may include a first chemical solution storage 1452, a second chemical solution storage 1458, and a mixing portion 1459. The first chemical solution storage 1452 is connected by a line that supplies the first chemical solution directly to the nozzle 1410 and a line that supplies it to the mixing portion 1459. For example, the first chemical solution may be hydrogen water, and a second chemical solution may be an alkaline cleaning solution. However, the present disclosure is not limited to this. The alkaline cleaning solution may be a first standard cleaning solution (SC1), which is an aqueous solution of hydrogen peroxide (H₂O₂) and ammonium hydroxide (NH₄OH). The mixing portion 1459 supplies a mixed chemical solution of the first and second chemical solutions to the nozzle 1410. The concentration ratio of the first chemical solution to the second chemical solution in the mixed solution may be appropriately adjusted because a low concentration of the second chemical solution may reduce contaminant removal efficiency, whereas a high concentration of the second chemical solution may damage metal patterns.

The sonic oscillator 1700 includes an ultrasonic nozzle 1710, an arm 1712, and a drive unit 1714. The ultrasonic nozzle 1710 is designed to vibrate by vibration or oscillation energy. The sonic oscillator 1700 is installed at one end of the movable arm 1712. The tip of the ultrasonic nozzle 1710 contacts the chemical solution provided on the substrate 500. A vibrator installed on the tip of the ultrasonic nozzle 1710 causes the ultrasonic nozzle 1710 to vibrate, transmitting the vibration to the chemical solution to agitate it. The intensity of vibration may be controlled according to power supplied to the vibrator. The chemical solution is sprayed from the nozzle 1410 of the chemical solution supplier 1400 onto the upper surface of a mask. The chemical solution may be supplied to the center of the upper surface of the substrate 500. The ultrasonic nozzle 1710 moves over the substrate 500 during processing and stands by at the home port 100 before and/or after processing.

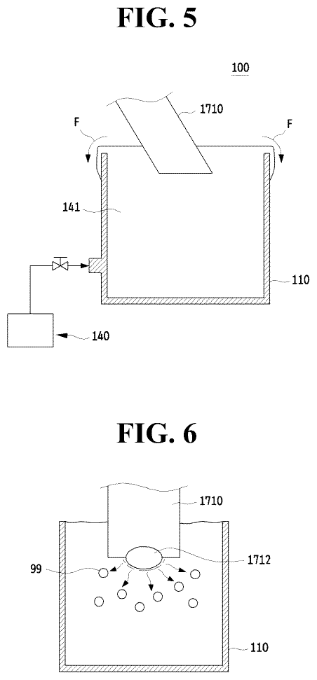

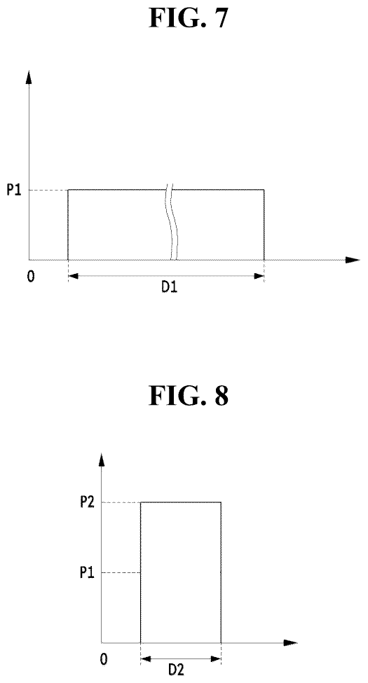

FIG. 4 is a flowchart illustrating the operation of the substrate processing apparatus according to some embodiments of the present disclosure. FIGS. 5 and 6 are conceptual views illustrating a cleaning operation of the ultrasonic nozzle. FIG. 7 is a diagram illustrating a substrate cleaning operation using the ultrasonic nozzle. FIG. 8 is a diagram illustrating an ultrasonic nozzle cleaning operation.

Referring to FIGS. 2 through 4, a substrate 500 is introduced into the chamber 1100, and cleaned during a cleaning period CP1 by ultrasonically vibrating the substrate 500 using the aforementioned method.

Thereafter, the cleaned substrate 500 exits the chamber 1100, and the ultrasonic nozzle 1710 waits within the home port 100 during a standby period SB1.

Then, another substrate 500 is introduced into the chamber 1100 and cleaned during a cleaning period CP2 by ultrasonic vibration, as described above.

The cleaned substrate 500 then exits the chamber 1100, and the ultrasonic nozzle 1710 stands by within the home port 100 during a standby period SB2.

Thereafter, yet another substrate 500 is introduced into the chamber 1100 and cleaned during a cleaning period CP3 by ultrasonic vibration.

The cleaned substrate 500 exits the chamber 1100, and the ultrasonic nozzle 1710 stands by within the home port 100 during a standby period SB3.

Thereafter, still another substrate 500 is introduced into the chamber 1100 and cleaned during a cleaning period CP4 by ultrasonic vibration.

Thus, the substrate cleaning processes CP1, CP2, CP3, and CP4 and the standby periods SB1, SB2, and SB3 within the home port 100 are repeated.

According to some embodiments, the ultrasonic nozzle 1710 may be cleaned while standing by within the home port 100 (see SB1, SB2, SB3).

Referring to FIG. 5, the home port 100 includes a bath 110 with an opening at the top and a cleaning solution supplier 140 configured to supply cleaning solution 141 to the bath 110. The cleaning solution may be deionized water (DIW), but is not limited thereto. The cleaning solution supplier 140 continuously supplies the cleaning solution 141 to one side of the bath 110. The supplied cleaning solution 141 overflows the bath 110, as indicated by an arrow F. In other words, the cleaning solution 141 flows over the side wall and outside of the bath 110.

Referring to FIG. 6, with the ultrasonic nozzle 1710 submerged in the cleaning solution 141, the vibrator 1712 operates and causes it to vibrate. Thus, particles 99 adhering to the ultrasonic nozzle 1710 detach. As the cleaning solution 141 overflows the bath 110, particles 99 falling off the ultrasonic nozzle 1710 also flow out of the bath 110.

Since the overflow speed of the cleaning solution 141 is not fast, if the ultrasonic nozzle 1710 does not vibrate within the home port 100, the particles 99 adhering to the ultrasonic nozzle 1710 may not detach due to the cleaning solution 141. The particles 99 adhering to the ultrasonic nozzle 1710 may subsequently contaminate a substrate 500 during cleaning. However, as in the substrate processing apparatus according to some embodiments of the present disclosure, if the ultrasonic nozzle 1710 vibrates by the operation of the vibrator 1712 while standing by within the home port 100, the particles 99 adhering to the ultrasonic nozzle 1710 may be easily removed.

The vibration pattern of the ultrasonic nozzle 1710 (i.e., the vibration pattern of the vibrator 1712) may vary depending on whether the ultrasonic nozzle 1710 is used for substrate cleaning or for ultrasonic nozzle cleaning.

For example, as illustrated in FIG. 7, during substrate cleaning, the ultrasonic nozzle 1710 (i.e., the vibrator 1712) operates at a first output P1 for a first duration D1.

In contrast, as illustrated in FIG. 8, during ultrasonic nozzle cleaning, the ultrasonic nozzle 1710 operates at a second output P2 for a second duration D2. The second output P2 may be greater than the first output P1, and the second duration D2 may be shorter than the first duration D1. The second output P2 may be the maximum output of the ultrasonic nozzle 1710 (i.e., the vibrator 1712).

If the vibration of the ultrasonic nozzle 1710 during substrate cleaning is too strong, it may adversely affect the substrate 500. Therefore, the ultrasonic nozzle 1710 vibrates at a preset output. Conversely, since the purpose of ultrasonic nozzle cleaning is to remove the particles 99 adhering to the ultrasonic nozzle 1710, the ultrasonic nozzle 1710 may vibrate at the highest possible output.

Further, during substrate cleaning (see CP1, CP2, CP3, and CP4), the ultrasonic nozzle 1710 operates at a first pulse repetition frequency, and during standby periods (see SB1, SB2, and SB3), the ultrasonic nozzle 1710 may operate at a second pulse repetition frequency higher than the first pulse repetition frequency. Operating at a higher frequency during standby facilitates easier removal of adhering particles 99.

Additionally, during standby periods (see SB1, SB2, and SB3), the ultrasonic nozzle 1710 may vibrate while stationary in the bath 110. To further facilitate particle removal, the ultrasonic nozzle 1710 may vibrate while moving up and down within the bath 110.

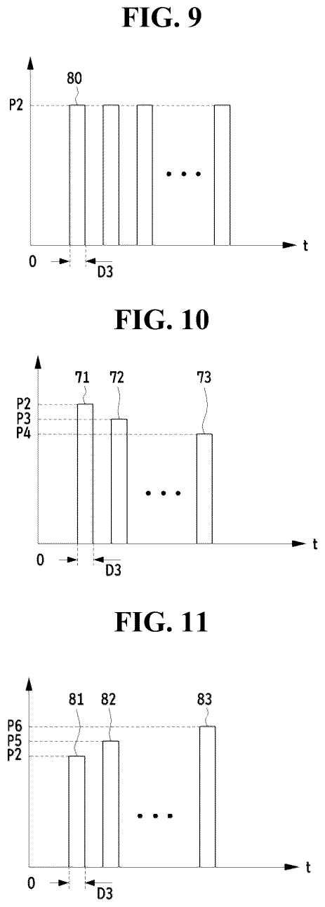

FIGS. 9 to 11 are diagrams illustrating other ultrasonic nozzle cleaning operations. For simplicity, differences from the ultrasonic nozzle cleaning operation described above with reference to FIGS. 4 to 8 will be mainly explained.

Referring to FIG. 9, during ultrasonic nozzle cleaning, a vibration on/off operation may be repeatedly performed to remove the particles 99 adhered to the ultrasonic nozzle 1710.

As illustrated, the ultrasonic nozzle 1710 may repeatedly operate at the second output P2 for a third duration D3. The third duration D3 may be shorter than the second duration D2 (FIG. 8). By repeatedly turning vibration on/off for short intervals, the particles 99 adhered to the ultrasonic nozzle 1710 (i.e., the vibrator 1712) can be more easily detached.

In FIG. 9, all output pulses 80 are illustrated as having the same duration and the same output, i.e., the third duration D3 and the second output P2, but are not limited thereto. For example, the duration of each output pulse 80 may be changed while repeatedly turning vibration on/off. That is, the duration of each output pulse 80 may gradually increase or decrease.

FIGS. 10 and 11 illustrate that the ultrasonic nozzle 1710 vibrates at at least two different outputs during standby periods.

Referring to FIG. 10, when short vibration on/off cycles are repeated, the output of vibration may be gradually lowered. As illustrated, a first output pulse 71 occurs over the third duration D3 with the second output P2, a second output pulse 72 occurs over the third duration D3 with a third output P3, and the third output pulse 73 occurs over the third duration D3 with a fourth output P4. The second output P2 is greater than the third output P3, and the third output P3 is greater than the fourth output P4.

Referring to FIG. 11, when short vibration on/off cycles are repeated, the output of vibration may be gradually increased. As illustrated, a first output pulse 81 occurs over the third duration D3 with the second output P2, a second output pulse 82 occurs over the third duration D3 with a fifth output P5, and a third output pulse 83 occurs over the third duration D3 with a sixth output P6. The second output P2 is less than the fifth output P5, and the fifth output P5 is less than the sixth output P6.

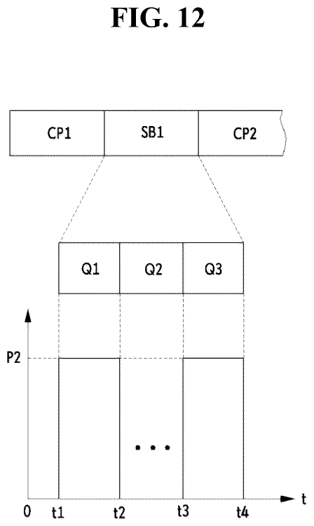

FIG. 12 is a diagram illustrating yet another ultrasonic nozzle cleaning operation. For convenience of description, differences from the ultrasonic nozzle cleaning operations described above with reference to FIGS. 4 to 11 will be mainly explained.

Referring to FIG. 12, a standby period SB1 may include first, second, and third consecutive periods Q1, Q2, and Q3.

During the first period Q1, the ultrasonic nozzle 1710 vibrates. Between times t1 and t2, the ultrasonic nozzle 1710 may vibrate at the second output P2. The cleaning solution 141 is continuously supplied to one side of the bath 110 in the home port 100. In this state, strong vibration of the ultrasonic nozzle 1710 in the home port 100 causes particles 99 to fall into the cleaning solution 141.

During the second period Q2, vibration of the ultrasonic nozzle 1710 stops. Between the time t2 and a time t3, the ultrasonic nozzle 1710 is stationary. Since the cleaning solution 141 is continuously supplied to one side of the bath 110 and overflows, particles 99 that fell off the ultrasonic nozzle 1710 also exit the bath 110.

During the third period Q3, the ultrasonic nozzle 1710 vibrates again. Between the time t3 and a time t4, the ultrasonic nozzle 1710 may vibrate again at the second output P2. To remove particles 99 not detached during the first period Q1, the ultrasonic nozzle 1710 may vibrate again. Upon conclusion of the third period Q3, the ultrasonic nozzle 1710 exits the home port 100.

The vibration during the third period Q3 is optional.

That is, only the first and second periods Q1 and Q2 may be performed, and after the second period Q2, the ultrasonic nozzle 1710 may exit the home port 100.

The second period Q2 is provided after the first period Q1 because if the ultrasonic nozzle 1710 is immediately removed from the bath 110, particles 99 may reattach to the ultrasonic nozzle 1710 on the surface of the cleaning solution 141 filled in the bath 110 when the ultrasonic nozzle 1710 leaves the bath 110. During a predetermined time of the second period Q2, particles 99 have sufficient time to exit the bath 110. The ultrasonic nozzle 1710 needs to be removed from the bath 110 after the predetermined time to prevent particle reattachment.

Also, after the third period Q3, there may not be a separate second period Q2. The vibration during the third period Q3 is preliminary, and the number of particles 99 falling from the ultrasonic nozzle 1710 during the third period Q3 may be quite small. Therefore, if the overall cleaning time (i.e., the length of the standby period SB1) is insufficient, a separate second period Q2 may be omitted after the third period Q3.

Also, during the cleaning periods (e.g., CP1), the ultrasonic nozzle 1710 may operate at a first pulse repetition frequency, whereas during the first and third periods Q1 and Q3, the ultrasonic nozzle 1710 may operate at a second pulse repetition frequency higher than the first pulse repetition frequency.

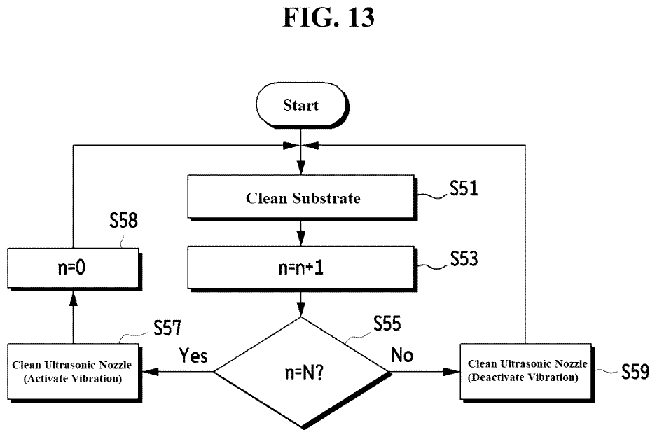

FIG. 13 is a flowchart illustrating the operation of the substrate processing apparatus according to some embodiments of the present disclosure.

Referring to FIG. 13, if a preset number of substrates 500 have not been processed, the ultrasonic nozzle 1710 does not vibrate in the home port 100 during standby periods (e.g., SB1). Once the processing of the preset number of substrates 500 is complete, the ultrasonic nozzle 1710 vibrates in the home port 100 during standby periods.

First, a substrate 500 is cleaned (S51). Specifically, the substrate 500 is placed on the support member 1300 and rotated while the chemical solution supplier 1400 supplies chemical solution. When the chemical solution is applied to the substrate 500, the ultrasonic nozzle 1710 vibrates to vibrate the chemical solution on the substrate 500.

Thereafter, a count n of cleaned substrates 500 is incremented (i.e., n=n+1) (S53). The cleaned substrate 500 is then removed from the chamber 1100, and the ultrasonic nozzle 1710 moves to the home port 100.

Thereafter, it is determined whether the count n has reached a preset number N (S55).

If the count n has reached the preset number N, the ultrasonic nozzle 1710 is submerged in the bath 110 and vibrated (S57). The count n is reset to zero (S58).

If the count n has not reached the preset number N, the ultrasonic nozzle 1710 is submerged in the bath 110 without vibration (S59).

Although embodiments of the present disclosure have been described above with reference to the accompanying drawings, one of ordinary skill in the art will understand that various modifications and other equivalent embodiments can be made without departing from the technical spirit or essential characteristics of the present disclosure. Accordingly, the above-described embodiments are to be understood as illustrative in all respects and not limiting.

What is claimed is:

1. A substrate processing apparatus comprising:
a support member configured to support a substrate;
a chemical solution supplier configured to supply chemical solution to the substrate;
a sonic oscillator including an ultrasonic nozzle;
a home port provided on one side of the support member and configured to accommodate the ultrasonic nozzle in a standby state; and
a controller configured to control the support member, the chemical solution supplier, the sonic oscillator, and the home port,
wherein the controller controls the ultrasonic nozzle to vibrate the chemical solution applied on the substrate during a cleaning period, and controls the ultrasonic nozzle to vibrate in the home port during a standby period to remove particles adhering to the ultrasonic nozzle.

2. The substrate processing apparatus of claim 1, wherein
during the cleaning period, the ultrasonic nozzle vibrates at a first output, thereby vibrating the chemical solution applied to the substrate, and
during the standby period, the ultrasonic nozzle vibrates at a second output higher than the first output in the home port.

3. The substrate processing apparatus of claim 1, wherein during the standby period, the ultrasonic nozzle vibrates at a maximum output within the home port.

4. The substrate processing apparatus of claim 1, wherein
during the cleaning period, the ultrasonic nozzle operates at a first pulse repetition frequency, and
during the standby period, the ultrasonic nozzle operates at a second pulse repetition frequency higher than the first pulse repetition frequency.

5. The substrate processing apparatus of claim 1, wherein
the home port includes: a bath having an opening at the top; and a cleaning solution supplier configured to supply cleaning solution to the bath, and
the cleaning solution supplier continuously supplies cleaning solution into the bath, thereby causing the cleaning solution to overflow the bath.

6. The substrate processing apparatus of claim 5, wherein the ultrasonic nozzle vibrates while moving up and down within the bath.

7. The substrate processing apparatus of claim 5, wherein
the standby period includes first and second consecutive periods,
during the first period, the ultrasonic nozzle vibrates, and
during the second period, the ultrasonic nozzle stops vibrating.

8. The substrate processing apparatus of claim 7, wherein
the standby period further includes a third period following the second period, and
during the third period, the ultrasonic nozzle vibrates again.

9. The substrate processing apparatus of claim 1, wherein during the standby period, the ultrasonic nozzle vibrates at at least two different outputs within the home port.

10. The substrate processing apparatus of claim 1, wherein
if a preset number of substrates have not been processed, the ultrasonic nozzle does not vibrate in the home port during the standby period, and
if the preset number of substrates have been processed, the ultrasonic nozzle vibrates in the home port during the standby period.

11. A substrate processing apparatus comprising:
a rotary chuck configured to support a substrate;
a chemical solution supplier configured to supply chemical solution to the substrate;
a sonic oscillator including an ultrasonic nozzle that vibrates by a vibrator's vibration;
a home port provided on one side of the rotary chuck and configured to accommodate the ultrasonic nozzle in a standby state; and
a controller configured to control the rotary chuck, the chemical solution supplier, the sonic oscillator, and the home port,
wherein
the home port includes: a bath with an opening at the top; and a cleaning solution supplier configured to supply cleaning solution to the bath,
the cleaning solution supplier continuously supplies cleaning solution into the bath, causing the cleaning solution to overflow,
during a cleaning period, the ultrasonic nozzle vibrates at a first output to vibrate the chemical solution applied on the substrate,
during a standby period, the ultrasonic nozzle is submerged in the cleaning solution through the opening of the home port,
the standby period includes consecutive first, second, and third periods,
during the first period, the ultrasonic nozzle vibrates at a second output greater than the first output, thereby detaching particles from the ultrasonic nozzle,
during the second period, the ultrasonic nozzle stops vibrating and the detached particles overflow out of the bath with the cleaning solution, and
during the third period, the ultrasonic nozzle vibrates again.

12. The substrate processing apparatus of claim 11, wherein during the third period, the ultrasonic nozzle vibrates again at a third output greater than the first output.

13. The substrate processing apparatus of claim 11, wherein
during the cleaning period, the ultrasonic nozzle operates at a first pulse repetition frequency, and
during the first and third periods, the ultrasonic nozzle operates at a second pulse repetition frequency higher than the first pulse repetition frequency.

14. A method for driving a substrate processing apparatus, the method comprising:
placing a substrate on a support member;
supplying chemical solution onto the substrate;
cleaning the substrate by vibrating the chemical solution applied on the substrate using an ultrasonic nozzle;
moving the ultrasonic nozzle to a home port; and
removing particles adhering to the ultrasonic nozzle by vibrating the ultrasonic nozzle in the home port.

15. The method of claim 14, wherein
the ultrasonic nozzle vibrates at a first output, thereby vibrating the chemical solution applied on the substrate to clean the substrate, and
the ultrasonic nozzle vibrates at a second output higher than the first output in the home port.

16. The method of claim 14, wherein the ultrasonic nozzle operates at a first pulse repetition frequency during substrate cleaning, and operates at a second pulse repetition frequency higher than the first pulse repetition frequency in the home port.

17. The method of claim 14, wherein
the home port includes: a bath with an opening at the top; and a cleaning solution supplier configured to supply cleaning solution to the bath, and
the cleaning solution supplier continuously supplies cleaning solution to the bath, causing the cleaning solution to overflow.

18. The method of claim 17, wherein the ultrasonic nozzle vibrates while moving up and down within the bath.

19. The method of claim 17, wherein
the standby period includes consecutive first and second periods,
during the first period, the ultrasonic nozzle vibrates, thereby detaching particles from the ultrasonic nozzle, and
during the second period, vibration of the ultrasonic nozzle stops, and the detached particles overflow out of the bath with the cleaning solution.

20. The method of claim 19, wherein
the standby period further includes a third period following the second period, and
during the third period, the ultrasonic nozzle vibrates again.
